(19) United States
(12) Patent Application Publication
(10) Pub. No.: US 2009/0001404 A1
(43) Pub. Date: Jan. 1, 2009

(54) SEMICONDUCTOR LIGHT EMITTING DEVICE, PROCESS FOR PRODUCING THE SAME, AND LED ILLUMINATING APPARATUS USING THE SAME

(76) Inventor: Takafumi OHATA, Hiroshima (JP)

Correspondence Address: BIRCH STEWART KOLASCH & BIRCH, PO BOX 747, FALLS CHURCH, VA, 22040-0747, US

(21) Appl. No.: 12/113,326

(22) Filed: May 1, 2008

(30) Foreign Application Priority Data
Jun. 29, 2007 (JP) 2007-172281
Dec. 14, 2007 (JP) 2007-323478

(51) Int. Cl. H01L 33/00

(52) U.S. Cl. 257/99; 438/26; 257/E33.062

(57) ABSTRACT

The present invention provides a semiconductor light emitting device comprising: a wiring substrate in which a pair of positive and negative electrodes are formed on a front surface of an insulating substrate, an LED arranged over one of the electrodes, or arranged to stretch over both of the electrodes and connected electrically to the positive and negative electrode pair, and a metal frame having, at the inner circumferential side thereof, a tapered face and arranged around the electrode pair on the front surface of wiring substrate, wherein the metal frame is jointed to the front surface of the wiring substrate through an adhesive layer, and a plating layer is formed on a surface of the metal frame and surfaces of the electrode pair.

### CROSS-REFERENCES TO RELATED APPLICATIONS

This application is related to Japanese patent application Nos. 2007-172281 filed on Jun. 29, 2007 and 2007-323478 filed on Dec. 14, 2007 whose priorities are claimed under 35 USC § 119, the disclosures of which are incorporated by reference in their entirety.

### BACKGROUND OF THE INVENTION

1. Field of the Invention

The present invention relates to a semiconductor light emitting device, a process for producing the same, and an LED illuminating apparatus using the same.

2. Description of the Related Art

Various semiconductor light emitting devices using a light emitting diode (LED) have been developed as a backlight for liquid crystal display devices, or for general lighting. About a package for each of these semiconductor light emitting devices, various structures are suggested in order to radiate visible rays emitted from the LED therein effectively in a predetermined direction to enhance the brightness and further release the heat generated from the LED effectively (see JP-A-2006-165138 and JP-A-2004-241509).

The semiconductor light emitting device as disclosed in JP-A-2006-165138 has a structure wherein an LED is mounted on a bi-layered wiring substrate, the LED on the wiring substrate is surrounded by a frame member made of resin, and a molding resin is filled into the frame member to seal the LED. The wiring substrate has, on the front surface thereof, a pair of positive and negative electrodes, and the LED is jointed to one of the electrodes, which is a chip-mounting land, by action of a soldering material (such as gold, a tin alloy, or a silver paste) to connect the two electrically with each other. The other electrode, which is a connecting land, is electrically connected to the upper face of the LED through a gold wire (having a diameter of about 50 μm) or the like.

In this semiconductor light emitting device, out of light rays emitted from the LED, light rays which are to diffuse toward the vicinity of the LED are reflected on inner wall faces of the frame member so as to be directed in the direction substantially perpendicular to the wiring substrate. Heat radiated from the LED is conducted through the chip-mounting land, which is made of metal, to wiring on the rear surface, and further conducted from external terminals to external electrodes connected thereto through a soldering material not illustrated.

In the semiconductor light emitting device as disclosed in JP-A-2004-241509, an LED is subjected to flip-chip-mounting on a pair of positive and negative electrode lands formed on the front surface of a wiring substrate. Around the LED, a frame member obtained by molding a metal having a high reflectivity, such as aluminum, is jointed onto an insulating layer of the wiring substrate through an adhesive layer.

According to this semiconductor light emitting device, the frame member is made of metal; thus, the member has a higher reflectivity than frame members made of resin. Moreover, heat generated in the LED is conducted from the electrode lands on the front surface side through filled vias to an electrode layer on the rear surface, and further conducted to external wiring.

As described above, in the semiconductor light emitting device as disclosed in JP-A-2006-165138, its frame member is made of resin, so that the reflectivity is smaller than that of any frame member made of metal. Thus, the efficiency of using light is also low. In particular, when the wavelength of light from its LED is turned shorter from blue wavelengths to violet wavelengths, the reflectivity lowers remarkably. Furthermore, the resin frame member is denatured to be discolored into yellow.

In the semiconductor light emitting devices as disclosed in JP-A-2006-165138 and JP-A-2004-241509, the efficiency of using light rays radiated onto the surface of their wiring substrate out of light rays emitted from their LED is low, and additionally their path through heat is released is also long so that a sufficient heat-releasing efficiency is not obtained. Furthermore, when the frame member is bonded onto the wiring substrate with an adhesive, it is necessary to control conditions for heating and pressing precisely in order for the adhesive not to be pushed out from the bonding face of the frame member.

### SUMMARY OF THE INVENTION

In light of the problems, the present invention has been made. An object thereof is to provide a semiconductor light emitting device making it possible to improve the efficiency of using light and the efficiency of releasing heat, a process for producing the same, and an LED illuminating apparatus using the same.

Thus, according to an aspect of the present invention, provided is a semiconductor light emitting device comprising: a wiring substrate in which a pair of positive and negative electrodes are formed on a front surface of an insulating substrate, an LED arranged over one of the electrodes, or arranged to stretch over both of the electrodes and connected electrically to the positive and negative electrode pair, and a metal frame having, at the inner circumferential side thereof, a tapered face and arranged around the electrode pair on the front surface of wiring substrate, wherein the metal frame is jointed to the front surface of the wiring substrate through an adhesive layer, and a plating layer is formed on a surface of the metal frame and surfaces of the electrode pair.

According to another aspect of the present invention, provided is a process for producing a semiconductor light emitting device, comprising the steps of: (A) forming a wiring substrate having a pair of positive and negative electrodes on a surface of an insulating substrate, (B) making a through hole in a thin metal plate to form a metal frame, (C) jointing the metal frame to a surrounding area of the electrode pair on the front surface of the wiring substrate through an adhesive layer to form a laminate, (D) forming a plating layer on a surface of the metal frame and surfaces of the electrodes, and (E) setting an LED over one of the electrodes or setting an LED to stretch over both of the electrodes through the plating layer, thereby connecting the LED electrically to the positive and negative electrode pair.

According to still another aspect of the invention, provided is an LED illuminating apparatus using the semiconductor light emitting device.

According to the semiconductor light emitting device of the invention, light rays emitted toward the metal frame out of light rays emitted from the LED are reflected on the plated tapered face while light rays emitted toward the wiring substrate are reflected on the plated surfaces of the first and second electrodes, so as to be directed into a direction substantially perpendicular to the direction parallel with the wiring substrate. As a result, the light-using efficiency of the LED is largely improved.

### BRIEF DESCRIPTION OF THE DRAWINGS

FIGS. 1A and 1B illustrate an embodiment 1 of the semiconductor light emitting device of the present invention, wherein FIG. 1A is a plan view thereof, and FIG. 1B is a sectional view thereof;

FIGS. 2A to 2E are views for explaining producing steps of the semiconductor light emitting device of the embodiment 1;

FIGS. 3A to 3C are views for explaining producing steps subsequent to the steps illustrated in FIG. 2;

FIGS. 4A to 4C are views for explaining producing steps subsequent to the steps illustrated in FIG. 3;

FIGS. 5A to 5C are views for explaining producing steps subsequent to the steps illustrated in FIG. 4;

FIGS. 6A to 6C are views for explaining producing steps subsequent to the steps illustrated in FIG. 5;

FIGS. 7A to 7D are views for explaining a semiconductor light emitting device of an embodiment 2 of present invention;

FIG. 8 is a plan view illustrating a semiconductor light emitting device of an embodiment 3 of the present invention;

FIG. 9 is a sectional view illustrating a semiconductor light emitting device of an embodiment 4 of the present invention;

FIGS. 10A and 10B illustrate a semiconductor light emitting device of an embodiment 5 of the present invention, wherein FIG. 10A is a plan view thereof, and FIG. 10B is a sectional view thereof;

FIG. 11 is a sectional view of a first modified example of the embodiment 5;

FIG. 12 is a sectional view of a second modified example of the embodiment 5;

FIG. 13 is a sectional view illustrating a semiconductor light emitting device of an embodiment 6 of the present invention;

FIG. 14 is a sectional view illustrating a semiconductor light emitting device of an embodiment 7 of the present invention; and

FIG. 15 is a partial sectional view illustrating an example of an LED illuminating apparatus using semiconductor light emitting devices of the present invention.

### DETAILED DESCRIPTION OF THE INVENTION

The semiconductor light emitting device of the present invention is a device comprising: a wiring substrate in which a pair of positive and negative electrodes are formed on a front surface of an insulating substrate, an LED arranged over one of the electrodes, or arranged to stretch over both of the electrodes and connected electrically to the positive and negative electrode pair, and a metal frame having, at the inner circumferential side thereof, a tapered face and arranged around the electrode pair on the front surface of the wiring substrate, wherein the metal frame is jointed to the front surface of the wiring substrate through an adhesive layer, and a plating layer is formed on the front surface of the metal frame and surfaces of the electrode pair.

In short, the semiconductor light emitting device of the invention has a structure wherein a plating layer is formed not only on the front surface of its metal frame but also on the front surface of an electrode pair on its wiring substrate, thereby reflecting light rays directed toward the wiring substrate also, out of light rays emitted from its LED, on the plating layer, so as to improve the efficiency of using the light rays.

The following will describe each of constituents which constitute this semiconductor light emitting device, and the structure of the device.

The insulating substrate is not particularly limited as long as the substrate is a substrate having electric non-conductance on its surface. The insulating substrate is, for example, a resin film substrate, a glass substrate, a ceramic substrate, or a semiconductor substrate having, on its surface, an insulating layer. The thickness thereof is suitably from about 150 to 800 μm. In the invention, the insulating substrate is preferably a substrate having no light transmissivity and white color, which gives a high surface-reflection efficiency for visible rays, for the following reason: when light from the LED passes through the insulating substrate, a reflection loss of the light is generated.

In the case of using, as the insulating substrate, for example, a resin film substrate, this film substrate is made white by using a resin film into which a filler is incorporated as the resin film substrate. For this reason, the efficiency of reflecting light from the LED which is radiated onto the resin film substrate can be made higher. Thus, as the whole of the semiconductor light emitting device, the light-using efficiency can be made even higher. In this case, it is preferred to use a resin film substrate formed by kneading a filler such as silica into a resin. The resin may be, for example, epoxy resin.

The material of the positive and negative electrode pair is not particularly limited as long as the material has electric conductivity and a plating layer can be formed on a surface of a solid object made of the material. The material is preferably a material which is bonded to the insulating substrate and is easily cut integrally therewith. As the material of the positive electrode and that of the negative electrode, the same electroconductive materials or electroconductive materials different from each other may be used. In order to make the production process simple, the positive electrode and the negative electrode are preferably made of the same material. At least the electrode on which the LED is mounted is preferably made of an electroconductive material having a high thermal conductivity in order for the electrode to conduct heat from the LED and release the heat outside. Examples of this material include copper and copper alloys.

The shape of the positive electrode and that of the negative electrode are not particularly limited, and may be equal to or different from each other. Examples thereof include a triangle, a rectangle, a circle, an ellipse, a ring shape, a “C”-like shape, “I”-like shape, and any combination thereof.

The positive and negative electrode pair is electrically connected to a wiring pattern formed on at least one of the front surface and the rear surface of the insulating substrate. This matter will be described in detail later.

The material of the metal frame is not particularly limited as long as the material is a metallic material and a plating layer can be formed on a surface of a solid object made of the metallic material. The material may be equal to or different from the materials of the positive and negative electrode pair.

The shape of the metal frame is a shape of a ring when the frame is viewed from the above thereof since the frame is arranged around the electrode pair, as described. Additionally, the metal frame has, at the inner circumferential side thereof, a tapered face. This tapered face is a face on which light from the LED is effectively reflected in a direction perpendicular to the insulating substrate. The ring shape is not particularly limited as long as the shape is a shape capable of surrounding the electrode pair. The metal frame is preferably made into a size and a shape making it possible to make the frame as close to the electrode pair as possible in order to improve the efficiency of reflecting light from the LED and make the size of the semiconductor light emitting device small.

The material of the adhesive layer is not particularly limited as long as the material makes it possible to bond the metal frame onto the front surface of the wiring substrate. The material may be a thermosetting adhesive, an optically curable adhesive, or the like. Examples of the thermosetting adhesive include an epoxy resin adhesive and a polyimide resin adhesive. These thermosetting adhesives are each preferably a sheet-form adhesive in a semi-cured state. An example of the optically curable adhesive is an acrylic resin adhesive. The front surface of the wiring surface, onto which the metal frame is bonded through the adhesive layer, is classified into: the front surface of a metal layer that remains when the electrode pair is pattern-formed and is made of a material equal to that of the electrodes; and the front surface of the insulating substrate that is exposed by removing this metal layer. This matter will be described in detail later.

The material of the plating layer is not particularly limited as long as the material is a material with which the electrode pair and the metal frame can be satisfactorily plated. The plating layer may be made of a single layer or plural layers. The topmost layer of the plating layer is preferably a layer having a high efficiency of reflecting light from the LED.

The LED used in the present invention may be an LED having, on one surface thereof and the surface opposite thereto, positive and negative electrodes, respectively, and an LED having, on only one surface thereof, positive and negative electrodes. In the former LED, the electrode on the jointed face (the rear surface) side thereof is electrically connected to one of the electrodes of the wiring substrate through a soldering material and further the electrode on the front surface side thereof is electrically connected to the other electrode of the wiring substrate by wire bonding. In the latter LED, the electrode pair thereof is electrically connected to the electrode pair on the wiring substrate through a soldering material.

### Structure of the Semiconductor Light Emitting Device:

In the semiconductor light emitting device of the present invention, in order to reflect light on the plating layer to improve the light-using efficiency, it is more preferred that the occupation area of the electrode pair in the inner region inside the metal frame on the wiring substrate surface is larger. In other words, no plating layer is formed on the insulating layer surface in the wiring substrate surface; therefore, it is more preferred that the area of the naked insulating layer in the inner region inside the metal frame is smaller.

The front surface of the metal frame and the front surface of one of the electrodes may be connected to each other through the plating layer. In this manner, the occupation area of the plating layer in the above-mentioned inner region becomes larger. The area of the naked insulating layer is conversely made smaller, so that the light-using efficiency can be made still higher.

When one of the electrodes is connected to the metal frame through the plating layer, the gap between the electrode and the metal frame is preferably made into such a small dimension that the gap is embedded with the plating layer, which is very thin. For example, the gap is preferably about 0.1 mm or less, more preferably 50 μm or less. The electrode may be brought into contact with the metal frame. In such a way, these front surfaces can be more easily connected to each other through the plating layer.

The electrode connected to the metal frame through the plating layer may be the positive electrode or the negative electrode, but is either one of these electrodes so as not to cause short circuit. In particular, when the LED is an LED having, on one surface thereof, positive and negative electrodes, the LED is subjected to flip-chip-mounting so as to stretch over the positive and negative electrodes of the wiring substrate; therefore, the electrode connected to the metal frame through the plating layer may be the positive electrode or the negative electrode. On the other hand, when the LED is an LED having, on one surface thereof and the surface opposite thereto, positive and negative electrodes, respectively, it is preferred that the wiring substrate electrode on which the LED is mounted is connected to the metal frame through the plating layer. In this way, heat from the LED can be effectively released to the metal frame through the plating layer.

As described above, in order to improve the light-using efficiency of the LED and the heat-releasing efficiency of the LED without causing short-circuit between the positive and the negative electrodes, it is preferred that in the above-mentioned inner region, the gap between the electrodes and the gap between the metal frame and the electrode not connected to the metal frame through the plating layer are made as narrow as possible as long as a predetermined electrostatic breakdown resistance is kept and further the portions other than the gaps wholly constitute the electrode surfaces.

As described above, the metal material of the metal frame is not particularly limited as long as a plating layer can be formed on a solid object made of the material. In order to make the heat releasing efficiency higher, the metal frame is preferably made of a metal having a high thermal conductivity, such as copper or copper alloy. Copper alloy is preferred from the viewpoint of the workability thereof into the metal frame. When the metal frame is made of pure copper, the frame is high in tenacity; therefore, when plural semiconductor light emitting devices formed on a single wiring substrate are divided into units each composed of a predetermined number of the devices, cutting for the division becomes difficult. When the cutting force is made large, a cut waste called burr is generated from the insulating layer (for example, a resin film) of the wiring substrate. For this reason, it is preferred that the metal frame is made of zinc copper alloy, nickel copper alloy, or chromium copper alloy, wherein an impurity such as Zn, Ni or Cr is added to copper in an amount of, e.g., 1% by weight or more to make the tenacity small.

In the present invention, the wiring substrate is not particularly limited as long as the substrate has, on the front surface thereof, a pair of positive and negative electrodes. The wiring substrate may have a monolayer wiring structure or a multilayer wiring structure.

The wiring substrate of a monolayer wiring structure may have a structure wherein a pair of positive and negative electrodes are formed on at least one surface of an insulating substrate and further a wiring pattern connected electrically to these electrodes is formed on at least one of the front surface (i.e., the electrode-formed surface) and the rear surface of the insulating substrate. The wiring pattern on the front surface or the rear surface is electrically connected to an external circuit for controlling turning-on or turning-off of the LED.

When the wiring substrate has the rear surface wiring pattern or has a multilayer wiring structure, which will be detailed later, it is preferred to use, as the insulating substrate, the above-mentioned resin film substrate in order to make the production of the light emitting device easy.

In the wiring substrate having the rear surface wiring pattern, one or more filled vias penetrating the insulating substrate are made to make it possible to connect the rear surface wiring pattern electrically to the positive and negative electrodes through the front surface wiring pattern or no front surface wiring pattern. In this case, about at least the filled via(s) for connecting the electrode on which the LED is mounted to the rear surface wiring pattern, it is preferred that the filled vias are made at two or more positions for at least one of the positive electrode and the negative electrode since heat from the LED can be effectively released to the rear surface wiring pattern and an external circuit connected thereto.

The wiring substrate of multilayer wiring structure type can be formed to have a structure wherein: onto the rear surface of a first wiring substrate of a monolayer wiring structure which has a rear surface wiring pattern as described above is laminated a second wiring substrate; and a wiring pattern of the second wiring substrate is electrically connected to the rear surface wiring pattern of the first wiring substrate. This second wiring substrate may have, for example, a structure having: an insulating substrate having a contact hole formed at the position of the rear surface wiring pattern of the first wiring substrate; an adhesive layer formed on the jointed face of the insulating substrate with the first wiring substrate; and a wiring layer extending from the face opposite to the jointed face into the contact hole so as to be electrically connected to the rear surface wiring pattern.

The insulating substrate used in the second wiring substrate is preferably a resin film substrate which is easily bonded to the first wiring substrate. Such a multilayer wiring structure has an advantage that paths for the wiring and the electrode area can be freely designed.

In the wiring substrate of monolayer or multilayer wiring structure type which has the wiring pattern on the rear surface, it is preferred that the rear surface is partially coated with a solder resist wherein a filler is kneaded into a resin. In this case, the rear wiring pattern is electrically connected to an external circuit with a soldering material; therefore, the solder resist is caused to adhere onto the portion of the rear surface wiring pattern onto which the soldering material is not caused to adhere. About this solder resist, the thermal conductivity thereof is made high by incorporating the filler into the resin. Thus, when the light emitting device is used for a long time so that the whole of the package becomes warm, the heat is conducted to the solder resist so that the heat can be effectively released. Examples of the resin used in the solder resist include epoxy resin, and acrylic resin. An example of the filler is silica.

In the semiconductor light emitting device of the present invention, it is allowable to lay a transparent resin layer that should be filled into at least the inner region of the metal frame, which is inside the frame, so as to protect the LED, as well as form the above-mentioned structure. It is further allowable to disperse, into this transparent resin layer, a fluorescent body which absorbs light rays having specific wavelengths out of light rays from the LED.

With reference to the drawings, the following will describe embodiments of the semiconductor light emitting device of the invention, and producing processes thereof in detail.

### EMBODIMENT 1

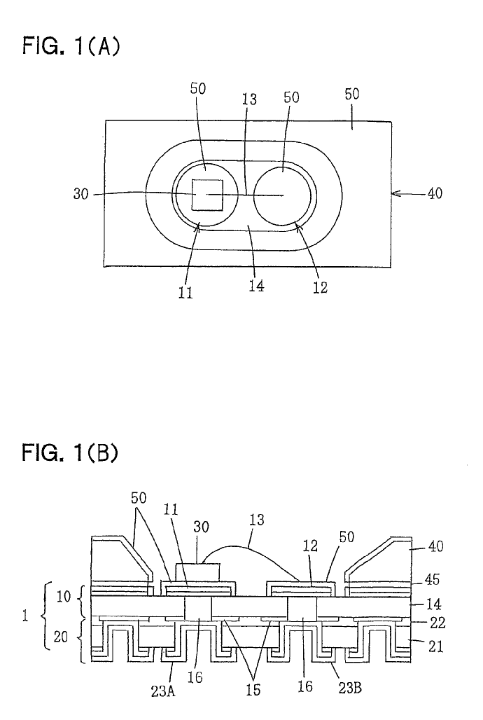

FIGS. 1A and 1B illustrate embodiment 1 of the semiconductor light emitting device of the present invention, and are a plan view thereof and a sectional view thereof, respectively.

This semiconductor light emitting device has a wiring substrate 1 of bilayer wiring structure type which has, on the front surface thereof, first and second electrodes 11 and 12; an LED 30 which is mounted on the first electrode 11, so as to be electrically connected through a die bonding paste to the electrode 11, and is further electrically connected to the second electrode 12 by wire bonding using a metal wire 13; and a metal frame 40 bonded to the front surface of the wiring substrate 1 through an adhesive layer 45.

The wiring substrate 1 has a first wiring structure portion 10 and a second wiring structure portion 20 laminated on the rear surface of the first wiring structure portion 10.

The first wiring structure portion 10 has a first resin film substrate 14, which may be referred to as a first substrate 14 hereinafter; the first and second electrodes 11 and 12, which are circular and are formed on the front surface of the first substrate 14; a rear surface wiring pattern 15 formed on the rear surface of the first substrate 14; and filled via 16 which penetrate the first substrate 14 so as to connect the first and second electrodes 11 and 12 electrically to the rear surface wiring pattern 15. One of the first and second electrodes 11 and 12 is a positive electrode, and the other is a negative electrode.

The second wiring structure portion 20 has a second resin film substrate 21, which may be referred to as a second substrate 21 hereinafter, an adhesive layer 22 formed on the jointed face of the second substrate 21 with the first wiring structure portion 10; contact holes made in the second substrate 21; and a wiring layer 23 which extends from the face of the second substrate 21 opposite to the jointed face of the substrate 21 into the contact holes so as to be electrically connected to the rear surface wiring pattern 15.

The metal frame 40 is made of the same metal material as the first and second electrodes 11 and 12 and is made of, for example, a copper alloy wherein Zn, Ni, Cr or the like is added to copper. The copper alloy is made of, for example, a copper alloy wherein 72% of Cu, 20% of Zn and 8% of Ni are mixed with each other. The metal frame 40 is a frame formed by punching out a plate made of the copper alloy and having a thickness of 0.3 to 0.5 mm to make a though hole.

The through hole in the metal frame 40 is a slender hole (i.e., a slot) surrounding the first and second electrodes 11 and 12 of the wiring substrate 1, and the inner wall face thereof is a substantially vertical face at the wiring substrate 1 side thereof. This inner wall face is tapered in such a manner that the face is inclined toward the outside so as to be made wider as the face is nearer to the opening edge at the side opposite to the wiring substrate 1. When the opening in the metal frame has different widths in accordance with directions, as in the slender hole illustrated in FIG. 1A, it is preferred that the tapered angle of the inner wall face portion in the direction along which the width is small is made larger than that of the inner wall face portion in the direction along which the width is large, that is, the former inner wall face portion is less widened.

Furthermore, a plating layer 50 is formed on the front surface of the metal frame 40 and the front surfaces of the first and second electrodes 11 and 12. When an object to be plated is made of copper or copper alloy, Ni is good in adhesiveness to copper but is easily oxidized to be blackened. Au is good in adhesiveness to Ni, but is low in reflectivity. Au is low in reflectivity, in particular, to blue light, which has short wavelengths; thus, Au is unsuitable for light emitting devices for emitting white, blue or green light. About such light emitting devices which can emit light having short wavelengths, it is preferred to plate their topmost surface with Ag. Thus, the plating layer 50 is preferably composed of plural plating layers obtained by using Ni, Au and Ag successively to carry out plating.

With reference to FIGS. 1 to 6, the following will describe a process for producing the light emitting device of embodiment 1. In the present specification with reference to the drawings, this process is a producing process for the single light emitting device. Of course, however, the present producing process can be applied to the case that plural light emitting devices are simultaneously produced on a single wiring substrate.

This process for producing the semiconductor light emitting device comprising the steps of: (A) forming the wiring substrate 1 having the positive and negative electrode pair 11 and 12 on the front surface of the insulating substrate, (B) making the through hole in the thin metal plate to form the metal frame 40, (C) jointing the metal frame 40 to the surrounding area of the electrode pair 11 and 12 on the front surface of the wiring substrate 1 through the adhesive layer 45, (D) forming the plating layer 50 on the surface of the metal frame 40 and the surface of the electrodes, and (E) setting the LED 30 over one of the electrodes through the plating layer 50, thereby connecting the LED electrically to the positive and negative electrode pair 11 and 12.

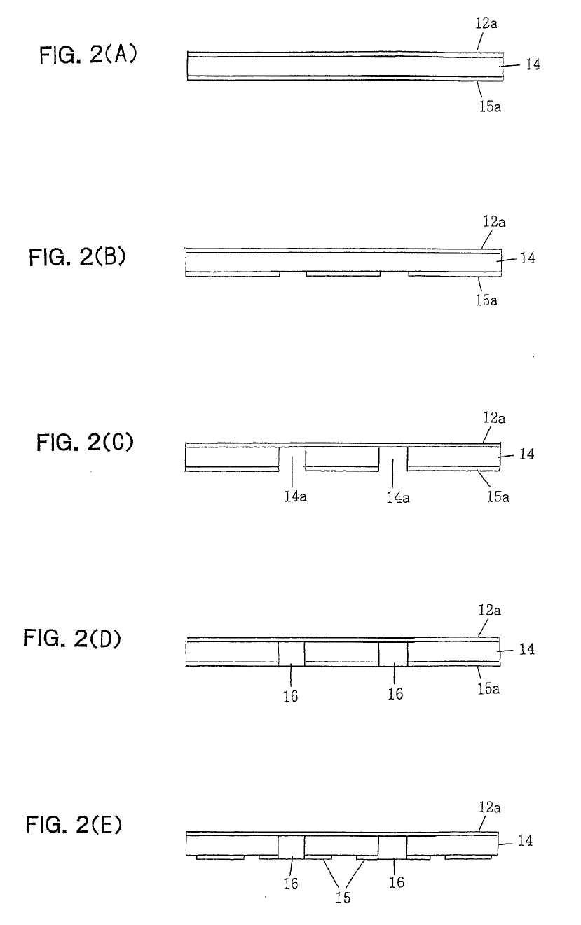

In the step (A), the formation of the first wiring structure portion 10 is first performed up to the middle way thereof by carrying out steps illustrated in FIGS. 2A to 2E successively.

As illustrated in FIG. 2A, metal layers 12a and 15a each made of copper foil and each having a thickness of about 12 μm are first formed on the front and rear surfaces of the first resin film substrate 14, which is, for example, a filler-containing epoxy film having a thickness of about 40 μm, respectively.

Next, as illustrated in FIG. 2B, predetermined regions of the rear metal layer 15a are etched off. As illustrated in FIG. 2C, the etched regions of the first substrate 14 are further subjected to laser-via processing so as to make the via holes 14a which have a diameter of about 100 to 150 μm. The positions where the via holes 14a are positions where the first and second electrodes 11 and 12 are to be formed. At this time, for one having a large dimension out of the electrodes, plural via holes 14a may be made. In this way, heat can be effectively conducted. The size of the via holes 14a is set in such a manner that the holes will be able to be filled in by copper plating in a subsequent step.

Subsequently, as illustrated in FIG. 2D, the surface metal layer 12a, which is copper foil exposed to the inside of the via holes 14a, is used as a nucleus to perform electroplating, thereby filling in the via holes 14a by copper plating. In this way, the filled vias 16 are made.

Next, as illustrated in FIG. 2E, the rear surface metal layer 15a is etched to electrically separate the filled via 16 at the first electrode side from the filled via 16 at the second electrode side. In this way, the rear wiring pattern 15 is formed which is electrically connected to each of the filled vias 16.

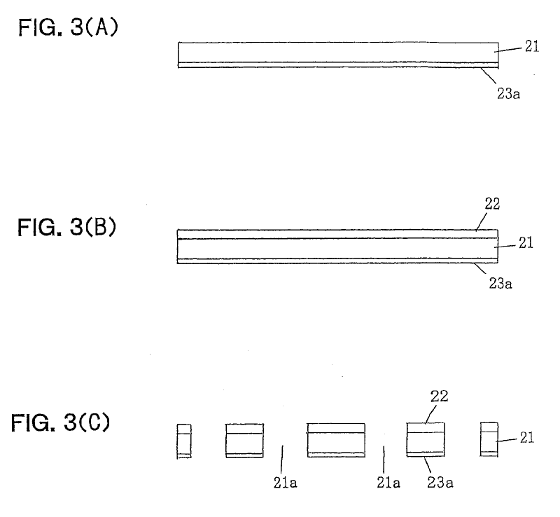

Next, the formation of the second wiring structure 20 is performed up to the middle way thereof by carrying out steps illustrated in FIGS. 3A to 3C successively.

As illustrated in FIG. 3A, a metal layer 23a made of copper foil and having a thickness of about 12 μm is first formed on one of the surfaces of the second resin film substrate 21, which is, for example, an epoxy film having a thickness of about 300 μm. Subsequently, as illustrated in FIG. 3B, the adhesive layer 22, which is an adhesive sheet having a thickness of about 40 μm in a semi-cured state, is laminated on the other surface of the second substrate 21.

Next, as illustrated in FIG. 3C, contact holes 21a each having a diameter of about 0.4 mm are formed at predetermined positions in the second substrate 21 having the metal layer 23a and the adhesive layer 22 with a drill. The contact holes 21a are each made to have a large diameter, thereby making the adhering area thereof large in order that at the time of soldering the vicinity of the contact holes onto the wiring substrate 1 in a subsequent step, the soldering material will easily enter the holes and further they will be able to be certainly fixed to each other. The positions where the contact holes 21a are formed are rendered the positions corresponding to the filled via 16 at the first electrode side and the filled via 16 at the second electrode side in the first wiring structure 10.

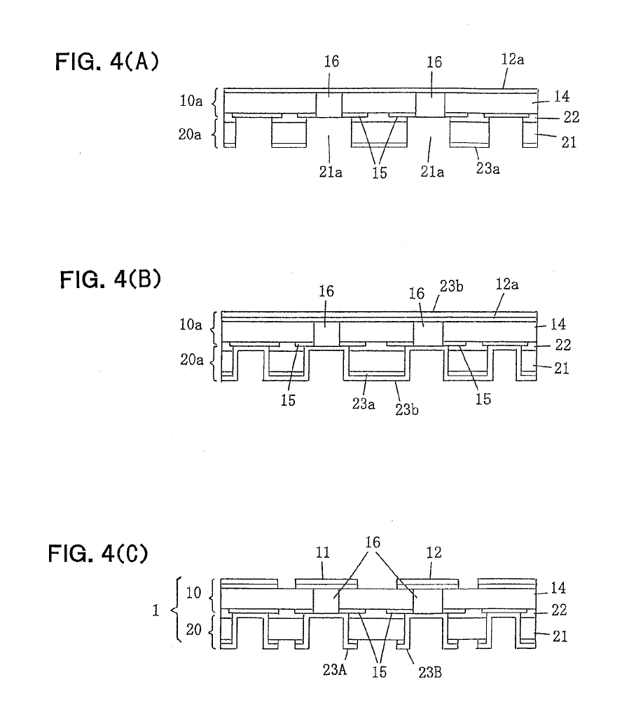

Next, as illustrated in FIG. 4A, the adhesive layer 22 of a second wiring structure portion intermediate 20a is caused to adhere onto the rear surface of a first wiring structure portion intermediate 10a. While the intermediates are pressed against each other to such a degree that the adhesive layer 22 is not pushed out into the contact holes 21a, the intermediates are heated to cure the adhesive layer 22.

Next, as illustrated in FIG. 4B, a metal layer 23b made of copper plating is formed on the whole of the rear surface of the second wiring structure portion intermediate 20a, which includes the inner surfaces of the contact holes 21a. At this time, in order to plate the workpiece to be plated wholly, the metal layer 23b is also formed on the front surface of the metal layer 12a of the first wiring structure portion intermediate 10a. By effect of the metal layer 23b, the metal layer 23a of the second wiring structure portion intermediate 20a is electrically connected to the rear surface wiring pattern 15 of the first wiring structure portion intermediate 10a through the contact holes 21a.

Next, the metal layers 23b and 12a of the first wiring structure portion intermediate 10a are patterned in a photolithographic or etching manner, so as to form the first and second electrodes 11 and 12. Additionally, the metal layers 23b and 23a of the second wiring structure portion intermediate 20a are patterned as illustrated in FIG. 4C, so as to form a wiring layer 23A connected electrically to the first electrode 11 and a wiring layer 23B connected electrically to the second electrode 12. In this way, the wiring substrate 1, wherein the first wiring structure portion 10 and the second wiring structure portion 20 are laminated, is formed. At this time, the first and the second electrodes 11 and 12 are formed into the form of a circle having such a size that this circle is close to the inner circumferential face of the through hole in the metal frame 40. In particular, the first electrode 11 on which the LED 30 is mounted is formed closely to the inner circumferential face to such a degree that only a slight gap (about 0.1 to 0.2 mm) is made between the first electrode 11 and the metal frame 40.

Plural pairs of first and second electrodes may be formed on this wiring substrate 1 so that plural LEDs can be mounted thereon, which is not illustrated.

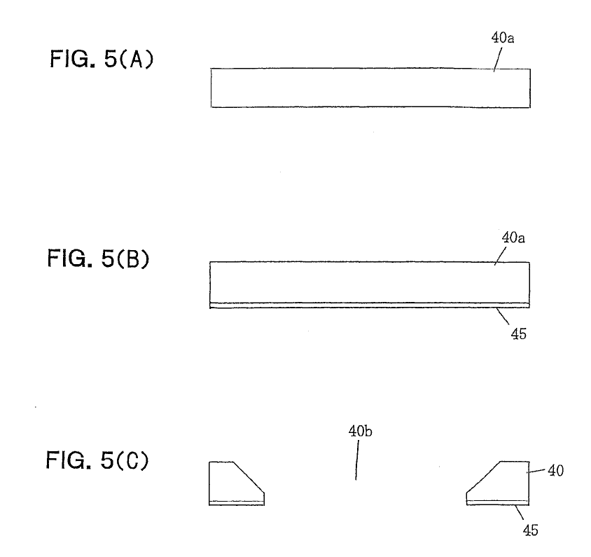

In the step (B), as illustrated in FIG. 5A, for example, a thin metal plate 40a made of copper alloy and having a thickness of about 300 μm is prepared. As illustrated in FIG. 5B, the adhesive layer 45, which is an adhesive sheet in a semi-cured state, is caused to adhere onto one of the surfaces of the thin metal plate 40a. The thickness of the adhesive layer 45 is about 20 μm.

Next, the thin metal plate 40a, which has the adhesive layer 45, is set into a mold to make a through hole 40b, thereby forming the metal frame 40, which is also illustrated in FIG. 5C. In the case that a great number of light emitting devices are formed, it is advisable to make plural through holes 40b into a matrix form in a single thin metal plate 40a, cause the resultant to adhere onto the wiring substrate 1 and then divide the resultant into the individual light emitting devices in a final step.

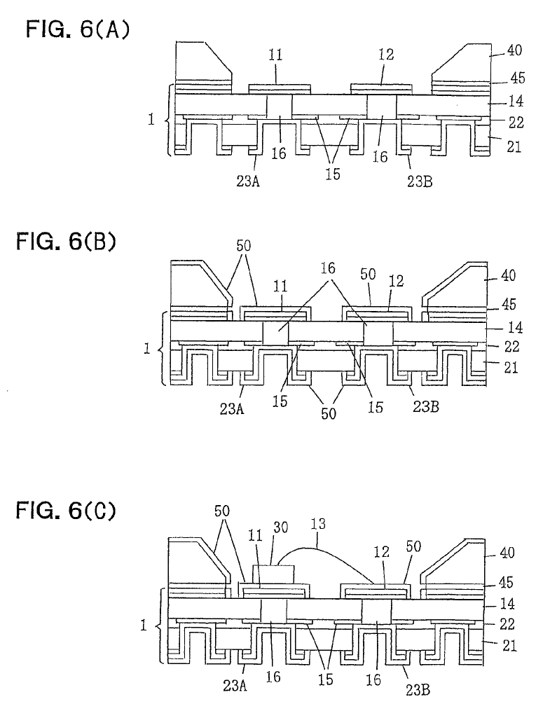

In the step (C), as illustrated in FIG. 6A, the adhesive layer 45 of the metal frame 40 is caused to adhere onto the front surface of the wiring substrate 1, and the resultant is set to a mold. At this time, the adhesion is performed while precise positioning is carried out in order for the adhesive layer 45 not to deviate from the upper of the metal layer in the vicinity of the first and second electrodes 11 and 12 on the front surface of the wiring substrate 1.

After the setting, through the mold, the wiring substrate 1 and the metal frame 40 are heated while pressed. If the pressure and the temperature are made high at this time, the adhesive force of the adhesive layer 45 becomes high; however, the wiring substrate 1 may be warped by a difference in linear expansion coefficient between the wiring substrate 1 and the metal frame 40, or the like. If the pressure is made too high, the adhesive layer 45 may be pushed out to the inside of the metal frame 40. Thus, the pressure is preferably about 1 kg/cm², which corresponds to a pressure obtained by pushing the substrate 1 and the frame 40 lightly by hand. The curing temperature is varied in accordance with the kind of the adhesive, and should be set to a temperature suitable for curing the adhesive (for example, 150° C. for about 60 minutes).

In the step (D), as illustrated in FIG. 6B, the plating layer 50 is formed into a thickness of about 0.5 to 6.0 μm onto the front surface of the metal frame 40 and the front surface of the first and second electrodes 11 and 12 of the laminate (see FIG. 6A), in which the wiring substrate 1 and the metal frame 40 are caused to adhere onto each other, by electroplating. At this time, the whole of the laminate is immersed in a plating bath; thus, the plating layer 50 is formed on any metal naked portion other than the front surfaces of the metal frame 40 and the first and second electrodes 11 and 12. As described above, this plating layer 50 is composed of three layers of Ni, Au and Ag layers, which are successively arranged upwards from the lowest of the plating layer 50. The plating layer 50 is neither formed on the naked surface of the first nor second substrate 14 or 21, and is not formed on the naked surface of the adhesive layer 45.

In this way, the metal frame 40 made of copper alloy and the regions where the first and second electrodes 11 and 12 are formed are covered with the silver plating, which has a high reflectivity, and the gap between the first electrode 11 and the metal frame 40 is buried by a width corresponding to the thickness of the plating layer 50.

In the step (E), as illustrated in FIG. 6C, the LED 30 is mounted on the first electrode 11 covered with the plating layer 50 through a soldering material to connect the lower electrode of the LED 30 electrically to the first electrode 11. The upper electrode of the LED 30 is electrically connected to the second electrode 12 by wire bonding using the metal wire 13 made of, for example, a gold line having a diameter of 50 μm.

In this way, the semiconductor light emitting device of embodiment 1 is completed.

In a subsequent step, a solder resist (not illustrated) containing a filler may be caused to adhere onto at least regions where no soldering material is stuck onto the metal layer 23A on the rear surface of the wiring substrate 1, that is, regions around the concaves corresponding to the filled vias 16. In this way, the heat releasing performance may be made high.

When plural semiconductor light emitting devices are produced all together, a single wiring substrate and a single metal frame are used to form the light emitting devices in a matrix form. Accordingly, the semiconductor light emitting devices are divided into individuals or units each made of a predetermined number of the devices. In order to produce a larger number of semiconductor light emitting devices per predetermined area in such a case, the intervals between the devices are narrow. Thus, precise cutting is required. When copper alloy is used as the material of the metal frame, the precise cutting can be attained for the following reason: copper alloy is smaller in tenacity than copper when the metal is cut integrally with the wiring substrate, which is made mainly of resin. The cut faces do not have the plating layer 50 made of Ni, Au and Ag. However, light from the LED is not required to be reflected on the faces; thus, no problem is caused.

According to the semiconductor light emitting device of embodiment 1 having the above-mentioned structure, light rays emitted toward the side of the metal frame 40 out of light rays emitted from the LED 30 are reflected on the plated tapered face, and light rays emitted toward the side of the wiring substrate 1 are reflected on the surfaces of the plated first and second electrodes 11 and 12 and the surface of the white first substrate 14, so as to be directed in a direction substantially perpendicular to the direction parallel to the wiring substrate 1. For this reason, the light-using efficiency of the LED 30 is largely improved. Heat generated from the LED 30 is mainly conducted from the first electrode 11 through the one or more filled vias 16 to the wiring layer 23A of the rear surface. Furthermore, the heat is conducted through the wiring layer 23A and the soldering material to electrically-connected external wiring or solder resist. Thus, a sufficient heat-releasing performance is obtained.

### EMBODIMENT 2

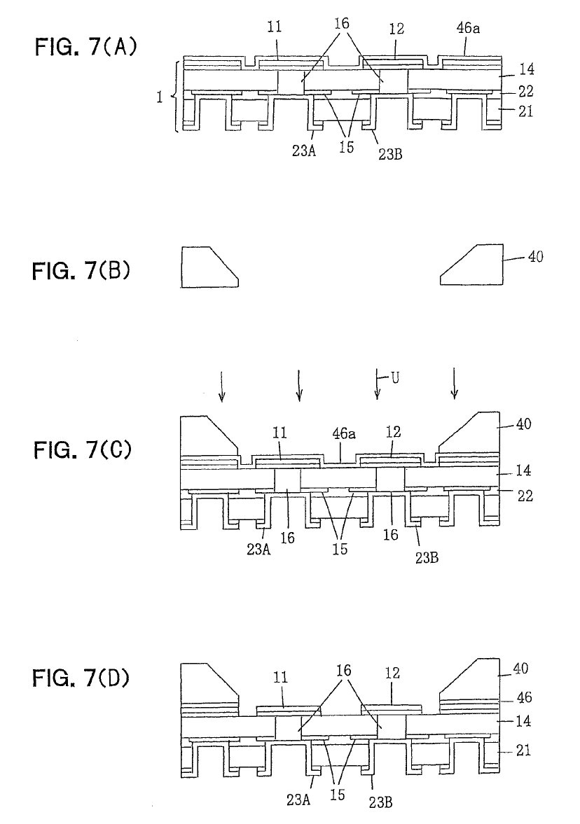

Embodiment 2 is a producing process different from the semiconductor light emitting device producing process in embodiment 1. Referring to FIGS. 7A to 7D, points of embodiment 2 different from embodiment 1 will mainly be described hereinafter. In FIGS. 7A to 7D, to the same elements as illustrated in FIGS. 1 to 6 are attached the same reference numbers, and description thereof is omitted.

In the producing process of embodiment 2, the wiring substrate 1 is formed in the same way as in the steps (A) and (B) in embodiment 1, which has been described with reference to FIGS. 2 to 4. Thereafter, in the step (C), the metal frame 40 is jointed to the front surface of the wiring substrate 1 through an adhesive layer. The method for the jointing is different from that in the step (C) in embodiment 1.

In the step (C) in embodiment 2, as illustrated in FIG. 7A, in a step (C1) a photosensitive adhesive is first painted into a thickness of about 5 to 25 μm onto the front surface of the wiring substrate 1, so as to form thereon a painted layer 46a of the adhesive.

This photosensitive adhesive is a positive type adhesive, wherein exposed regions can be dissolved in a developing solution, and may be, for example, an adhesive using an acrylic epoxy resin (acrylic-component modified epoxy resin (trade name: PSR-4000 W8) manufactured by TAIYO INK MFG. CO., LTD.). A first reason why this adhesive may be selected is that the adhesive is optically curable. A second reason therefor is that the adhesive is white so as to be high in reflectivity of light so that light can be prevented from leaking through the painted layer 46a of the photosensitive adhesive in the adhering face between the metal frame 40 and the first resin film substrate 14. As a result, it is possible to prevent a phenomenon that even regions of the painted layer 46a to which light is not radiated are optically sensitized so that bonding poorness is generated. A third reason therefor is that the adhesive less gives mist (tar) so that there is less caused a problem that the adhesive pollutes the first resin film substrate 14 when the painted layer 46a is cured. A fourth reason therefor is that the adhesive contains no halogen and thus even when the temperature of the semiconductor light emitting device is raised during the use thereof, the adhesive never corrodes the silver plating on the surfaces of the metal frame 40 and the first and second electrodes 11 and 12. The reason is particularly important when the semiconductor light emitting device is for cars or the like so that the device may be used at high temperature.

As illustrated in FIG. 7B, the metal frame 40 is formed in the same way as in embodiment 1. However, the material of the metal frame in embodiment 2 is different from any material similar to the material in embodiment 1 (the so-called nickel silver (Cu: 62-66%, Ni: 16.5-19.5%, Fe: 0.25% or less, Pb: 0.1% or less, and Zn: the balance (18% or less)), and is the so-called tough pitch copper (Cu component: 99.90% or more). A first reason therefor is that the tough pitch copper is good in adhesiveness to the adhesive. Another reason is that the tough pitch copper has advantages that: the copper is good in thermal conductivity so that the copper is suitable for articles which are used at high temperature; and the copper less imposes a burden on the environment since the copper contains no Pb.

The copper material that may be used is, for example, phosphor bronze or oxygen free high conductivity copper besides the above. Considering the thermal conductivity thereof, it is more preferred to use oxygen free high conductivity copper having a higher purity (Cu component: 99.96% or more). However, the workability involves a problem. On the other hand, phosphor bronze (Cu: 93-95%, Sn: 5.5-7%, and Pb: 0.03-0.35%) or nickel silver has a problem that Pb is contained in only a small amount.

Next, in a step (C2), as illustrated in FIG. 7C, the metal frame 40 is set onto the painted layer 46a of the photosensitive adhesive under the application of an appropriate pressure thereto. At this time, the photosensitive adhesive is transparent; therefore, the metal frame 40 is set onto the painted layer 46a with a high precision while the individual electrodes 11 and 12 and the metal layer in the vicinity thereof are checked through the painted layer 46a. In this case, it is unnecessary to control the pressure in such a manner that the adhesive will not be pushed out from the metal frame 40 as in embodiment 1.

Next, in a step (C3), as illustrated in FIG. 7C, light U is radiated onto the wiring substrate 1, on which the metal frame 40 is set, from the front surface side thereof, so as to expose externally-naked regions in the painted layer 46a to the light. At this time, the metal frame 40 functions as a mask. Developing treatment is then conducted to remove the exposed regions in the painted layer 46a. As illustrated in FIG. 7D, in this way, the surfaces of the first and second electrodes 11 and 12 and the surface of the first substrate 14 are made naked in the inner region of the metal frame 40.

Subsequently, the metal frame 40 and the wiring substrate 1 are heated while pressed, so as to cure the painted layer 46a between the metal frame 40 and the wiring substrate 1, thereby yielding a cured adhesive layer 46.

Thereafter, in the same way as in embodiment 1 described with reference to FIGS. 6B and 6C, the plating layer 50 is formed, the LED 30 is set onto the first electrode 11 to connect them electrically, and the LED 30 is electrically connected to the second electrode 12 through the metal wire 13.

According to the producing process of embodiment 2, the photosensitive adhesive is used for the adhesive layer 46, whereby the metal frame 40 can be used as a mask in the exposure to light. In this way, the adhesive can be removed in a self-aligning manner from electrode portions for which the adhesive is unnecessary. Thus, the jointing of the metal frame 40 to the wiring substrate 1 can easily be attained by a simple method. In other words, when an adhesive having no photosensitivity is painted onto the wiring substrate 1, it is necessary to mask the inner region of the metal frame 40 and paint the adhesive, thereby making the process complicated; however, such complicatedness is not caused in embodiment 2.

### EMBODIMENT 3

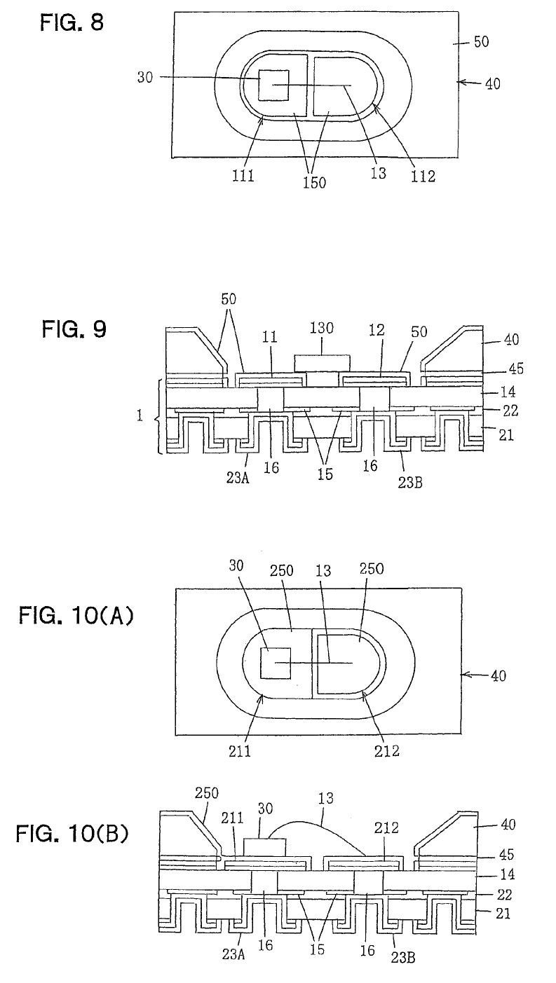

FIG. 8 is a plan view illustrating a semiconductor light emitting device of embodiment 3. In FIG. 8, to the same elements as illustrated in FIG. 1 are attached the same reference numbers.

This semiconductor light emitting device of embodiment 3 is a device produced by the producing process of embodiment 1 or 2; however, its first and second electrodes 111 and 112 are formed more largely than in embodiments 1 and 2.

In this manner, the area of a plating layer 150 in the inner region of the metal frame 40 is made larger, so that the light-using efficiency of the LED 30 can be made higher.

### EMBODIMENT 4

FIG. 9 is a sectional view illustrating a semiconductor light emitting device of embodiment 4. In FIG. 9, to the same elements as illustrated in FIG. 1 are attached the same reference numbers.

This semiconductor light emitting device of embodiment 4 is produced in the same way as in embodiment 1 except that: instead of the LED used in embodiment 1, an LED 130 having, on a singe surface side thereof, a pair of positive and negative electrodes; and this LED 130 is arranged to stretch over the first and second electrodes 11 and 12 so as to interpose a soldering material (not illustrated) and the plating layer 50 therebetween, thereby connecting the LED electrically to the electrodes.

According to this semiconductor light emitting device of embodiment 4, heat from the LED 130 is conducted from the first and second electrodes 11 and 12 through the individual filled vias 16 to each of the wiring layers 23A and 23B; therefore, a higher heat-releasing efficiency can be obtained than in embodiment 1. When the above-mentioned solder resist is bonded to both of the wiring layers 23A and 23B in this case, a still higher heat-releasing efficiency can be obtained.

### EMBODIMENT 5

FIGS. 10A and 10B illustrate a semiconductor light emitting device of embodiment 5, wherein FIG. 10A is a plan view thereof and FIG. 10B is a sectional view thereof. In FIGS. 10A and 10B, to the same elements as illustrated in FIG. 1 are attached the same reference numbers.

In the semiconductor light emitting device of embodiment 5, a first electrode 211 which is larger than the first electrode 111 in embodiment 3 illustrated in FIG. 8 is formed to set the gap between the first electrode 211 and the metal frame 40 to 0.1 mm or less. For this reason, the surface of the first electrode 211 is integrally connected to the surface of the metal frame 40 through a plating layer 250. The semiconductor light emitting device of embodiment 5 is produced in the same way as in embodiment 1 except that the sizes of the first electrode 211 and a second electrode 212 are changed.

In this way, the area of the plating layer 250 in the inner region of the metal frame 40 becomes larger than in embodiment 3; thus, the light-using efficiency of the LED 30 can be made higher.

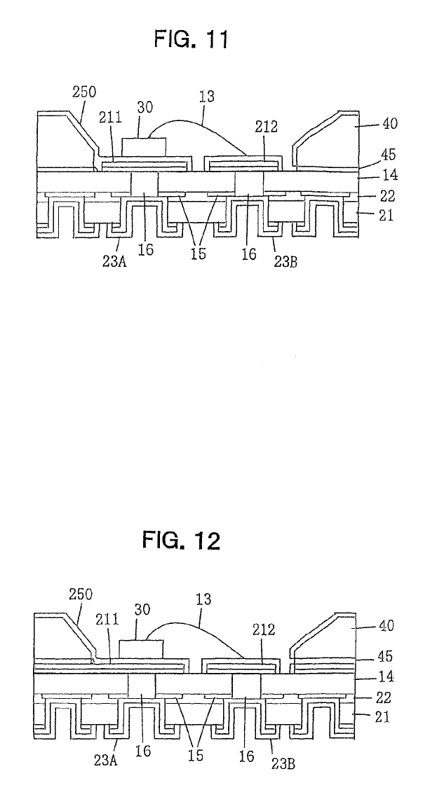

As in a first modified example of embodiment 5 illustrated in FIG. 11, any metal layer may be removed in the region where the metal frame 40 is located (i.e., the vicinity of the first and second electrodes 211 and 212), thereby bringing the adhesive layer 45 into direct contact with the first substrate 14. In this case, the adhesive force of the adhesive becomes larger than in the case of bringing the adhesive layer into contact with the metal layer.

As in a second modified example of embodiment 5 illustrated in FIG. 12, the metal layer in the region where the metal frame 40 is located may be connected to one of the electrodes. In this way, the plating layer on the metal frame 40 can easily be connected to the plating layer on one of the electrodes.

### EMBODIMENT 6

FIG. 13 is a sectional view illustrating a semiconductor light emitting device of embodiment 6. In FIG. 13, to the same elements as illustrated in FIG. 10 are attached the same reference numbers.

The semiconductor light emitting device of embodiment 6 can be produced in the same way as in embodiment 5 except that the front surface side of the semiconductor light emitting device of embodiment 5 is covered with a light transmissible resin layer 60 to protect the LED 30. This light transmissible resin layer 60 can be formed by setting the device illustrated in FIGS. 10A and 10B into a mold, injecting a photosensitive resin or a thermosetting resin into the mold, and radiating light thereto or heating the mold to cure the resin. Of course, it is allowable to use the amount of the resin to such a degree that the inside of the metal frame 40 is covered in without using any mold. In short, it is sufficient that the LED 30 and the metal wire 13 can be covered so as to protect them from impacts and so on from the outside.

A fluorescent body may be dispersed into the light transmissible resin layer 60, the situation being not illustrated. For example, in the case of using, as the LED 30, an LED emitting light rays from blue rays to ultraviolet rays and using, as the fluorescent body, a fluorescent body which absorbs the light from the LED 30 and emits light having a longer wavelength than the LED light, a semiconductor light emitting device which can emit light rays in various colors can be obtained. In the semiconductor light emitting device of the present invention, the frame as a reflecting body is made of metal, and further the frame is covered with the plating layer; thus, even when light rays emitted from the LED are rays from blue rays to ultraviolet rays, the reflecting body is neither discolored nor deteriorated by the light rays. Thus, the device is suitable for the case using the fluorescent body.

### EMBODIMENT 7

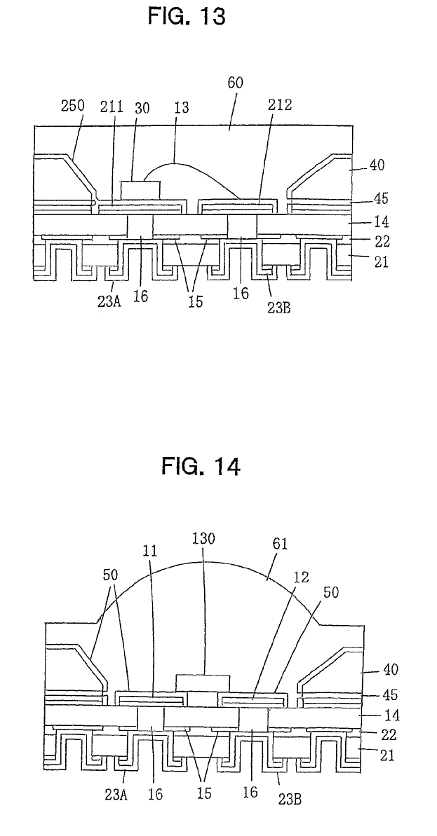

FIG. 14 is a sectional view illustrating a semiconductor light emitting device of embodiment 7. In FIG. 14, to the same elements as illustrated in FIG. 9 are attached the same reference numbers.

The semiconductor light emitting device of embodiment 7 can be produced in the same way as in embodiment 4 except that the front surface side of the semiconductor light emitting device of embodiment 4 is covered with a lens-shaped light transmissible resin layer 61 to protect the LED 130. This lens-shaped light transmissible resin layer 61 can be formed by setting the device illustrated in FIG. 9 into a mold, injecting a thermosetting resin into the mold, and heating the mold to cure the resin. The lens-shaped light transmissible resin layer 61 has a function of collecting direct light from the LED 130 and reflected light besides the function of protecting the LED 130. The above-mentioned fluorescent body may be dispersed in the lens-shaped light transmissible resin layer 61.

The semiconductor light emitting device of the present invention is not limited to embodiments 1 to 7; it is needless to say that the device may be a device wherein two or more from these embodiments may be appropriately combined with each other.

The shapes of the first and second electrodes and the shape and the size of the through hole in the metal frame may be freely designed or varied. In order to make the electrode area as large as possible to improve the reflection efficiency and the heat-releasing efficiency, for example, it is allowable to make a part of the first electrode on which the LED is mounted into the form of a circle contacting the metal frame, make the second electrode into a C-shaped form which surrounds the first electrode, and make the through hole in the metal frame into the form of a circle which surrounds the second electrode.

In embodiments 1 to 7 (see FIGS. 1 and 4C), exemplified have been cases wherein the metal frame 40 is jointed through the adhesive layer 45 onto the metal layer in the vicinity of the first and second electrodes 11 and 12 of the wiring substrate 1. It is however allowable that at the time of patterning the first and second electrodes 11 and 12, the metal layer in the vicinity thereof is removed and the metal frame 40 is jointed through the adhesive layer 45 onto the front surface of the first substrate 14 (see FIG. 11). This manner makes the gap between the first electrode 11 and the metal frame 40 narrow, so that these surfaces can easily be connected to each other through the plating layer 50.

### EMBODIMENT 8

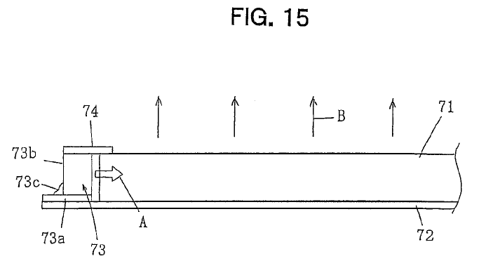

FIG. 15 is a partial sectional view illustrating an example of an LED illuminating apparatus using semiconductor light emitting devices of the invention.

This LED illuminating apparatus has a light conducting plate 71, a reflecting plate 72 made of metal and formed on the back surface of the light conducting plate 71, a light source unit 73 arranged in the periphery of the light conducting plate 71, and a reflecting frame 74 made of metal and formed on the front periphery of the light conducting plate 71. The apparatus is used as, for example, a backlight in a liquid crystal panel.

The light source unit 73 has a circuit substrate 73a, and semiconductor light emitting devices 73b connected electrically to wiring of the circuit substrate 73a through a soldering material 73c. Light rays (represented by an arrow A) from LEDs set in the individual semiconductor light emitting devices 73b are radiated into an end face of the light conducting plate 71. In this case, the semiconductor light emitting devices 73b are semiconductor light emitting devices according to one or more of embodiments 1 to 7. The devices are arranged on the circuit substrate 73a along a single line (in the direction perpendicular to the paper surface of FIG. 15) or along plural lines. It is needless to say that a product wherein plural light emitting devices are integrally formed is used instead of arranging the light emitting devices formed individually along a single line.

The light conducting plate 71 is made of a transparent resin such as acrylic resin. On the forward surface thereof is formed a light scattering pattern obtained by printing a white ink or the like thereon into a regular pattern.

According to the LED illuminating apparatus having the above-mentioned structure, the light rays A emitted from the individual semiconductor light emitting devices 73b incident on side surfaces of the light conducting plate 71 directly into the light conducting plate 71, or are reflected on the reflecting plate 72 or the reflecting frame 74 so as to be incident into the light conducting plate 71. The light rays A are then radiated out from the forward surface. Since the light scattering pattern is formed on the forward surface of the light conducting plate 71, at this time the vicinity of the semiconductor light emitting devices 73b is not particularly intensely luminous and light rays (represented by arrows B) are emitted with an even intensity from the entire forward surface of the light conducting plate 71.

The LED illuminating apparatus using the semiconductor light emitting device(s) of the invention is not limited to the apparatus of embodiment 8, and may be, for example, an indoor illuminating apparatus wherein a light source unit having the semiconductor light emitting devices arranged in a plane is arranged under a reflecting shade in the form of a concavely curved plane, or a flashlight wherein the semiconductor light emitting devices are arranged on a reflecting plate in the form of a concavely curved plane.

What is claimed is:

1. A semiconductor light emitting device comprising: a wiring substrate in which a pair of positive and negative electrodes are formed on a front surface of an insulating substrate, an LED arranged over one of the electrodes, or arranged to stretch over both of the electrodes and connected electrically to the positive and negative electrode pair, and a metal frame having, at the inner circumferential side thereof, a tapered face and arranged around the electrode pair on the front surface of the wiring substrate,
wherein the metal frame is jointed to the front surface of the wiring substrate through an adhesive layer, and
a plating layer is formed on a surface of the metal frame and surfaces of the electrode pair.

2. The semiconductor light emitting device according to claim 1, wherein the front surface of the metal frame and the surface of one of the electrodes are connected to the plating layer.

3. The semiconductor light emitting device according to claim 1, wherein the metal frame is made from a copper alloy.

4. The semiconductor light emitting device according to claim 1, wherein the wiring substrate has a rear surface wiring pattern on a rear surface of the insulating substrate, and
the rear surface wiring pattern is connected to the positive and negative electrode pair through a plurality of filled via made to penetrate the insulating substrate.

5. The semiconductor light emitting device according to claim 4, wherein the filled vias are made at two or more positions in at least one of the positive and negative electrodes.

6. The semiconductor light emitting device according to claim 4, wherein the insulating substrate is a resin film including a filler.

7. The semiconductor light emitting device according to claim 4, wherein the rear surface of the wiring substrate is partially coated with a solder resist wherein a filler is kneaded into a resin.

8. The semiconductor light emitting device according to claim 1, wherein the adhesive layer is made from a photosensitive adhesive.

9. A process for producing a semiconductor light emitting device, comprising the steps of:
(A) forming a wiring substrate having a pair of positive and negative electrodes on a front surface of an insulating substrate,
(B) making a through hole in a thin metal plate to form a metal frame,
(C) jointing the metal frame to a surrounding area of the electrode pair on the front surface of the wiring substrate through an adhesive layer,
(D) forming a plating layer on a surface of the metal frame and surfaces of the electrodes, and
(E) setting an LED over one of the electrodes or setting an LED to stretch over both of the electrodes through the plating layer, thereby connecting the LED electrically to the positive and negative electrode pair.

10. The process for producing a semiconductor light emitting device according to claim 9, wherein the step (C) comprises a step (C1) of painting a photosensitive adhesive onto the front surface of the wiring substrate, a step (C2) of setting the metal frame on the painted layer of the photosensitive adhesive, and a step (C3) of radiating light from the side of the wiring substrate front surface over which the metal frame is set toward the painted layer, thereby exposing the outwards-naked portion of the painted layer to the light, and ten developing the painted layer to remove the naked portion of the painted layer.

11. An LED illuminating apparatus, using the semiconductor light emitting device according to claim 1.
